(19) United States
(12) Patent Application Publication
(10) Pub. No.: US 2026/0191080 A1
(43) Pub. Date: Jul. 2, 2026

(54) PACKAGE STRUCTURE AND PACKAGE METHOD FOR ELECTRONIC DEVICE

(71) Applicant: STATS ChipPAC Semiconductor (Jiangyin) Co., LTD., Jiangyin (CN)

(72) Inventors: Hongli XU, Jiangyin (CN); Jian XU, Jiangyin (CN); Jianwen ZHANG, Jiangyin (CN)

(21) Appl. No.: 19/429,158

(22) Filed: Dec. 22, 2025

(30) Foreign Application Priority Data
Dec. 26, 2024 (CN) 202411938779.1

(51) Int. Cl. H10W 72/00; H10W 70/05; H10W 74/10; H10W 90/00

(52) U.S. Cl. CPC H10W 72/823; H10W 70/095; H10W 74/114; H10W 90/401

(57) ABSTRACT

A package structure and a package method for an electronic device are provided. The package structure includes: a first substrate; a plurality of solder pads on the first substrate; a conductive structure on the first substrate and electrically connected to the solder pads on the first substrate; a first insulating package body on an upper surface of the first substrate and covering at least a portion of sidewalls of the conductive structure; and an electronic device fixed on the first insulating package body and electrically connected to the solder pads on the first substrate through the conductive structure.

### CROSS-REFERENCE TO RELATED APPLICATIONS

This application claims the benefit of priority to Chinese Application No. CN202411938779.1, filed Dec. 26, 2024, which is incorporated herein by reference in its entirety.

### TECHNICAL FIELD

The present application relates to the field of electronic component package, and particularly relates to a package structure and a package method for an electronic device.

### BACKGROUND

Currently, molding is often used in electronic component package for protection and insulation, etc. In particular, some electronic devices are arranged above the molding body or at least a part of them need to be exposed outside the molding body. For example, optical devices that need to emit or receive light, pressure sensing chips, temperature-sensitive sensor chips, and sound-sensitive sensor chips, etc. In different micro-electro-mechanical systems (MEMS), various components such as microsensors, microactuators, and microstructures are typically included, and some microsensors are also exposed outside the molding body. These designs increase the difficulty and costs of the mold design for the molding body and affect the yield.

### SUMMARY

The present disclosure provides a package structure for an electronic device, which includes: a first substrate, the first substrate having on it a plurality of solder pads; a conductive structure located on the first substrate and electrically connected with the solder pads on the first substrate; a first insulating package body located on the upper surface of the first substrate and covering at least a part of the side walls of the conductive structure; and an electronic device fixed above the first insulating package body and electrically connected with the solder pads on the first substrate through the conductive structure.

In some embodiments, the conductive structure includes: a second substrate and conductive pillars located above it; and the second substrate is electrically connected with the solder pads on the first substrate through solder balls.

In the above embodiments, the conductive structure further includes a second insulating package body, the second insulating package body being arranged above the second substrate, packaging at least a part of the conductive pillars and exposing the top end of the conductive pillars.

In the above embodiments, the second insulating package body and the first insulating package body are formed in one-piece.

In some embodiments, the top of the conductive structure is flush with or higher than the upper surface of the first insulating package body.

In some embodiments, the package structure further includes an outer cover, which is located on the first substrate or the first insulating package body, and which is used to enclose the electronic device and the conductive structure.

In some embodiments, the outer cover is at least partially light-transmitting or is a non-sealed structure.

In some embodiments, other electronic devices are arranged on the first substrate, and are covered within the first insulating package body.

The present disclosure further provides a package method for an electronic device, which includes: fixing a conductive structure on a first substrate and electrically connecting it with solder pads of the first substrate; forming a first insulating package body above the first substrate through a molding process, and exposing the top of the conductive structure; and fixing an electronic device above the first insulating package body and electrically connecting it with the solder pads on the first substrate through the conductive structure.

In some embodiments, the manufacturing method for the conductive structure includes: forming a second insulating package body above the second substrate through a molding process; forming holes in the second insulating package body, one end of the holes is connected with the second substrate and another end runs through the upper surface of the second insulating package body; and plating and/or filling conductive material within the holes to form conductive pillars located above the second substrate.

In other embodiments, the manufacturing method for the conductive structure includes: arranging conductive pillars above the second substrate.

In the above embodiments, the manufacturing method for the conductive structure further includes: forming a second insulating package body above the second substrate through a molding process, packaging at least a part of the conductive pillars and exposing the top end of the conductive pillars.

In the above embodiments, through a molding process, is also able to form a first insulating package body above the first substrate, form a second insulating package body above the second substrate, package at least a part of the conductive pillars and expose the top end of the conductive pillars, simultaneously.

In the above embodiments, after fixing the electronic device above the first insulating package body and electrically connecting it with the solder pads on the first substrate through the conductive structure, the method further includes: arranging an outer cover on the first substrate or on the first insulating package body, and the outer cover is used to enclose the electronic device and the conductive structure.

In some embodiments, other electronic devices are arranged on the first substrate, the other electronic devices are subsequently covered within the first insulating package body.

### BRIEF DESCRIPTION OF THE DRAWINGS

FIG. 1 illustrates a schematic diagram of a package structure 1′ for electronic device in the related art;

FIG. 2 illustrates a top view schematic diagram of the package structure 1′ in FIG. 1;

FIG. 3 illustrates a schematic diagram of an embodiment of the package method 100 for an electronic device of the present disclosure;

FIG. 4 illustrates a top view schematic diagram of the first substrate 10 in the package method 100 for an electronic device of the present disclosure;

FIG. 5 illustrates a schematic diagram of step S10 in the package method 100 for an electronic device of the present disclosure;

FIG. 6 illustrates a top view schematic diagram of FIG. 5;

FIG. 7 illustrates a schematic diagram of step S20 in the package method 100 for an electronic device of the present disclosure;

FIG. 8 illustrates a top view schematic diagram of FIG. 7;

FIG. 9 illustrates a schematic diagram of step S30 in the package method 100 for an electronic device of the present disclosure;

FIG. 10 illustrates a top view schematic diagram of FIG. 9; and

FIG. 11 illustrates a schematic diagram of an optional step S40 in the package method 100 for an electronic device of the present disclosure.

### DETAILED DESCRIPTION

The present disclosure will be described in detail below in conjunction with specific embodiments. The following embodiments will assist those skilled in the art in further understanding the present disclosure, but are not intended to limit the scope of the present disclosure in any way. It should be noted that those ordinary skilled in the art may make various modifications and improvements without departing from the concept of the present disclosure. These are all within the scope of protection of the present disclosure.

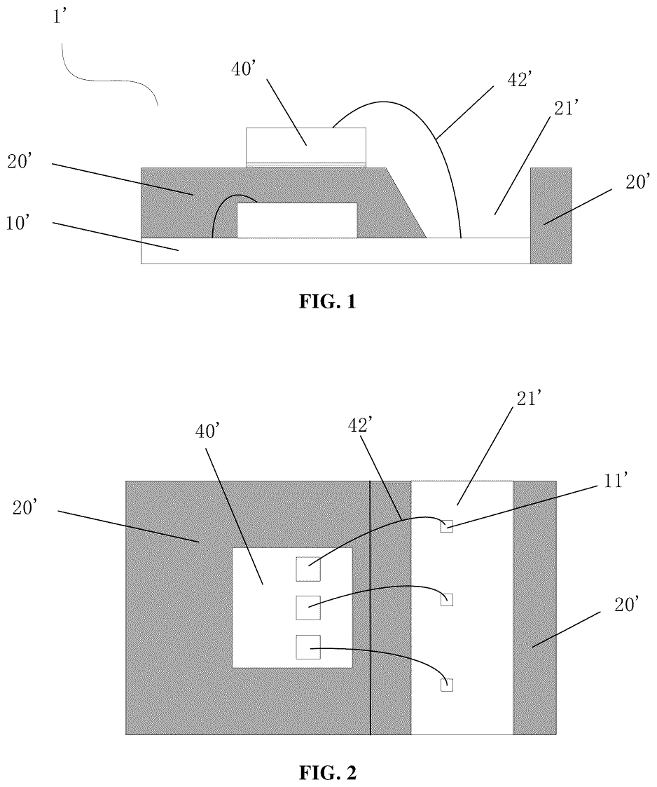

Currently, molding is often used in electronic component package for protection and insulation, etc., but some electronic devices need to be arranged above the molding body or at least a part of them need to be exposed outside the molding body. For example, optical devices that need to emit or receive light, pressure sensing chips, temperature-sensitive sensor chips, and sound-sensitive sensor chips, etc. In different micro-electro-mechanical systems (MEMS), various components such as microsensors, microactuators, and microstructures are typically included, and some microsensors also need to be exposed outside the molding body. Therefore, the irregular package structure 1′ as shown in FIG. 1 are sometimes used in the related art.

Since the chip 40′ needs to be exposed outside the molding body 20′, solder pads 11′ on the substrate 10′ corresponding to the chip 40′ also need to be exposed (see the top view schematic diagram of the package structure 1′ in FIG. 2), which results in the need for a recess portion 21′ to be arranged for the molding body 20′, thus significantly increasing the difficulty and costs of the mold design for the molding body 20′. Moreover, the height of the recess portion 21′ is low, and during the molding process, molding material tends to leak into the recess portion 21′, and covers or damages the solder pads 11′ or other electronic components in the recess portion 21′. In addition, the space inside the recess portion 21′ is narrow, so that wire bonding between the chip 40′ and the solder pads 11′ is difficult, and particularly when the number of leads 42′ is large, adhesion tends to occur, which affects the yield.

In the present disclosure, by arranging a conductive structure on the first substrate, the top surface of the conductive structure is exposed from the first insulating package body, such that the solder pads on the first substrate can form electrical connections with the electronic device above the first insulating package body through the conductive structure, which can reduce the difficulty and costs of designing and manufacturing the package mold, and reduce the difficulty and costs of the package process and the process for connection of the electronic device with the solder pads, and improve the yield.

FIG. 3 illustrates a schematic diagram of an embodiment of the package method 100 for an electronic device of the present disclosure. For example, package method 100 includes the following steps: S10, fixing a conductive structure on a first substrate and electrically connecting it with solder pads of the first substrate; S20, forming a first insulating package body above the first substrate through a molding process, and exposing the top of the conductive structure; S30, fixing an electronic device above the first insulating package body and electrically connecting it with the solder pads on the first substrate through the conductive structure.

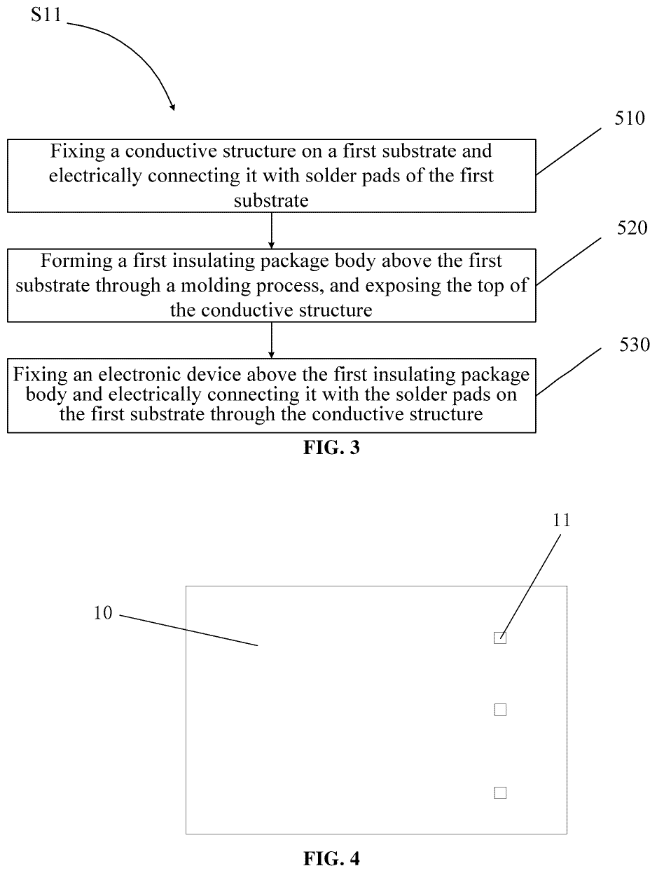

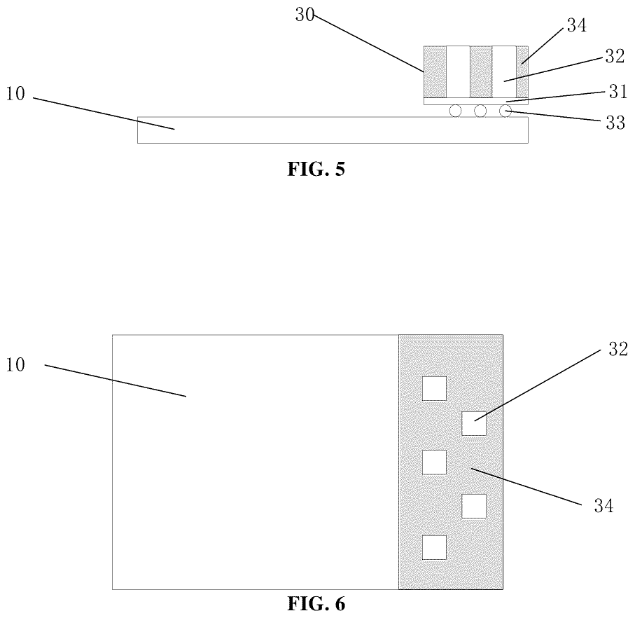

FIG. 4 illustrates a top view schematic diagram of the first substrate 10. The first substrate 10 in the present disclosure may be a circuit board, may be a lead frame (LF), and also may be a chip or an electronic device stacked below, and as long as it can provide solder pads 11 for electrical connection with conductive structure, it may be used as the first substrate 10.

FIG. 5 illustrates a schematic diagram of step S10 in the package method 100 for an electronic device of the present disclosure. In the figure, the conductive structure 30 is fixed on the first substrate 10 through solder balls 33 and electrically connected with the solder pads 11 on the first substrate 10 through the solder balls 33. At least one solder ball needs to be connected to each solder pad 11 that needs to be electrically connected with the conductive structure 30, and depending on the situation, multiple solder balls may also be connected with each solder pad 11, and more solder balls may also be connected outside the solder pads 11 to fix the conductive structure 30. For example, in FIG. 4, only one column of solder pads 11 on the first substrate 10 is shown, while in FIG. 5, three columns of solder balls 33 are arranged below the conductive structure 30, and the two columns of solder balls on the right are not connected to the solder pads 11 and only serve for fixing and balancing. In other embodiments, solder balls may not be used and alternative connection methods may be used, such as through-hole welding, etc.

Wherein one method for manufacturing the conductive structure 30 is as follows.

In S01a, a second insulating package body 34 is formed above the second substrate 31 through a molding process. The molding process specifically includes methods such as mold injection molding, etc., e.g., covering the area above the second substrate 31 with materials such as epoxy resin, etc., to form the second insulating package body 34.

In S02a, holes are formed in the second insulating package body 34, one end of the holes is connected with the second substrate 31 and another end runs through the upper surface of the second insulating package body 34. FIG. 6 illustrates a top view schematic diagram of FIG. 5, and it can be seen from the figure that along the direction perpendicular to the second substrate 31, two columns with a total of five holes are formed in the second insulating package body 34. The method for forming holes may be mechanical drilling, physical cutting, chemical etching, etc., the cross-sectional shape of the holes may be various shapes such as square, circle, rectangle, triangle, etc.

In S03a, conductive material is plated and/or filled within the holes to form conductive pillars 32 located above the second substrate 31. Conductive material can be plated on the inner walls of the holes through chemical or physical methods, etc., to form hollow conductive pillars 32; furthermore, the plated layer can be continuously thickened to enhance electrical conductivity. Solid conductive pillars 32 may also be directly formed by filling the holes with conductive material. In some embodiments, plating and filling methods may be used together. In some embodiments, the number of conductive pillars 32 is equal to or greater than the number of solder pads 11 that need to be electrically connected on the first substrate 10, the additional conductive pillars 32 may be used to provide backup electrical connection channels to improve the reliability and stability of the electrical connection. In some embodiments, the area of the conductive pillars 32 located at the top end of the upper surface of the second insulating package body 34 is greater than the area of the solder pads 11, which is conductive to reducing the difficulty of wire bonding and improving yield.

In some embodiments, the conductive structure 30 may be pre-designed according to the shape, size of the first substrate 10, and the shape, size and position of the solder pads 11, and is fully manufactured before step S10 to simplify the process and shorten the manufacturing. Since both the solder balls 33 and conductive pillars 32 may have redundancy, the conductive structure 30 may even serve as a modular structural component applicable to various different package structures.

In other embodiments, the conductive structure 30 may also use other manufacturing methods.

In S01b, conductive pillars 32 are arranged above the second substrate 31. The conductive pillars 32 may be made of various conductive materials, and in some embodiments, copper pillars are used; arranging methods may be welding, plug-in, etc.

In S02b, a second insulating package body 34 is formed above the second substrate 31 through a molding process, at least a part of the conductive pillars 32 is packaged and the top end of the conductive pillars 32 is exposed.

In some embodiments, the above steps S01b and S02b are both completed before step S10; in other embodiments, steps S01b and S02b may be completed fully or partially after step S10; in some embodiments, step S02b may also be merged with step S20.

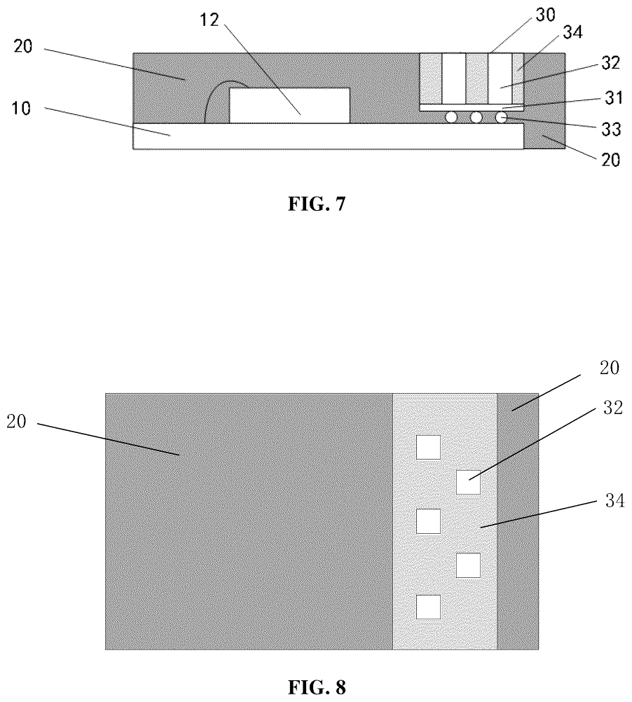

FIG. 7 illustrates a schematic diagram of step S20 in the package method 100 for an electronic device of the present disclosure, FIG. 8 illustrates a top view schematic diagram of FIG. 7. From the figures, it can be seen that a first insulating package body 20 is formed above the first substrate 10 through a molding process, and the first insulating package body 20 covers at least a part of the side walls of the conductive structure 30, electronic devices such as a chip, a transistor, a resistor, a capacitor, etc., above the first substrate 10 are all packaged inside (schematically shown as 12 in the figure). Since the conductive structure 30 is located on the first substrate 10 and the solder pads 11 are electrically connected with the solder balls 33 at the bottom of the conductive structure 30, it is impossible for the package material to cover or damage the solder pads 11, so as to affect its electrical connection; meanwhile, the package material may also flow into and fill the gaps below the second substrate 31, which protects the connection between the solder balls 33 and the solder pads 11. This significantly reduces the difficulty of designing and manufacturing the package mold, while also reducing the difficulty of package process, which is conductive for cost savings and improved yields.

In some embodiments, the top of the conductive structure 30 is flush with or higher than the first insulating package body 20, in order to prevent the package material from covering or damaging the top end of the conductive pillars 32 in the conductive structure 30 during the package process in step S20. When the top of the conductive structure 30 is flush with the first insulating package body 20, the tops of the two are located in the same plane, which facilitates the formation of the first insulating package body 20. In some embodiments, when the conductive structure 30 is located at the edge of the first substrate 10, a first insulating package body 20 on the outer side of the conductive structure 30 and the first substrate 10 may also be additionally arranged to enhance the protection for the conductive structure 30.

In embodiments where steps S02b and S20 are merged, the second substrate 31 is fixed on the first substrate 10 and arranged with conductive pillars 32 located above it, and then through a molding process such as injection molding, the first insulating package body 20 and the second insulating package body 34 are simultaneously formed, and the tops of the conductive pillars 32 are exposed. This can save a molding process to reduce production time and costs, and integrate the conductive structure 30 with the first insulating package body 20 into a whole, which improves structural strength. In some embodiments, the conductive pillars 32 may also be higher than the first insulating package body to avoid the package material covering the tops of the conductive pillars 32.

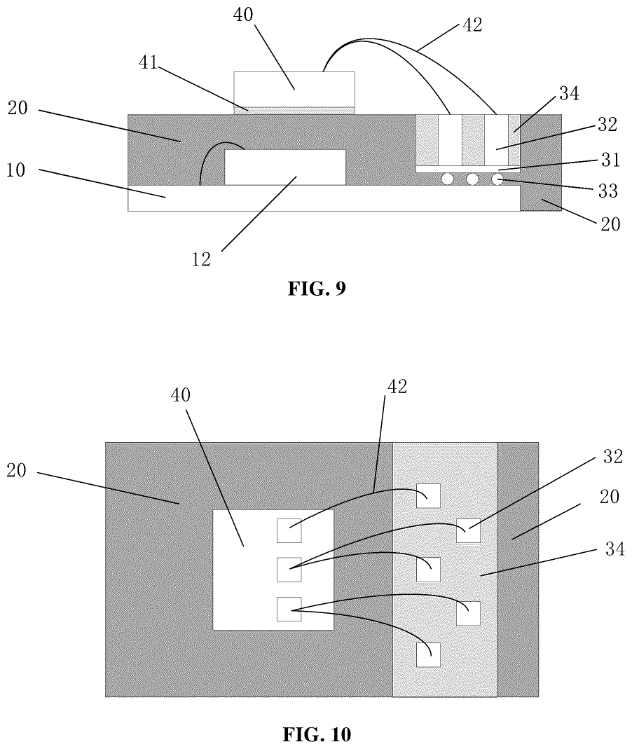

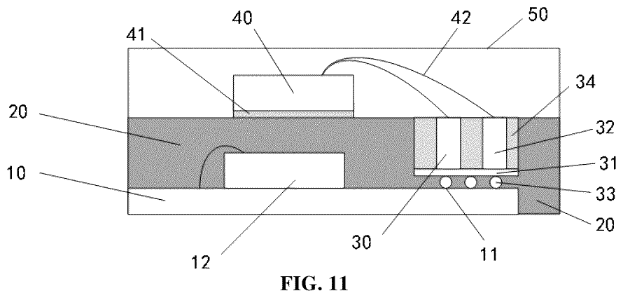

FIG. 9 illustrates a schematic diagram of step S30 in the package method 100 for an electronic device of the present disclosure; FIG. 10 illustrates a top view schematic diagram of FIG. 9. Electronic device 40 that needs to be exposed outside the first insulating package body 20, such as an optical device, a pressure sensing chip, a temperature-sensitive sensor chip, a sound-sensitive sensor chip, etc., is fixed above the first insulating package body 20. The fixing method may use method such as silver paste, die attach film (DAF), etc., the fixing material is schematically shown as 41 in the figure. The electronic device 40 may be connected with the top end of the conductive pillars 32 of the conductive structure 30 through a lead 42, and since the top end of the conductive pillars 32 are flush with or higher than the upper surface of the first insulating package body, the difficulty of wire bonding operation is low, which is conductive to improving yield. In some embodiments, the area of the top end of the conductive pillars 32 is greater than the area of the solder pads 11, which further reduces the difficulty of wire bonding. In other embodiments, the number of conductive pillars 32 is greater than the number of solder pads 11, and the additional conductive pillars 32 may also be connected to the electronic device 40 as backup electrical connection channels to improve the reliability and stability of electrical connection.

In some embodiments, the electronic device 40 may also be connected with the top end of the conductive pillars 32 using other means. For example, the electronic device 40 is mounted in a flip-chip manner above the conductive structure 30 and the first insulating package body 20, such that the connections between the electronic device 40 and the top end of the conductive pillars 32 are tighter, which can shorten the connection path, and improve the structural strength, and reduce failure rate.

In some embodiments, an optional step S40 is also included after step S30. FIG. 11 illustrates a schematic diagram of an optional step S40 in the package method 100 for an electronic device of the present disclosure. An outer cover 50 is arranged above the first substrate 10 or the first insulating package body 20, and the outer cover 50 is connected with the first substrate 10 or the first insulating package body 20 and is used to enclose the electronic device 40 and the conductive structure 30. The outer cover 50 can protect internal electronic components and leads, and serves for dustproofing, moisture resistance, corrosion resistance, and impact resistance. The outer cover 50 may be of metal material, resin material, etc., and its material and design are selected according to actual needs. For example, when the electronic device 40 is an optical device that requires light sensing, at least a part of the outer cover 50 should be able to transmit light; when the electronic device 40 needs to come into contact with the outside air, then the outer cover 50 may be arranged as a non-sealed structure, for example, at least one channel communicating with the outside is arranged.

The present disclosure further provides a package method for an electronic device, which can be manufactured using the aforementioned package method 100 for an electronic device, as shown in FIG. 11. It includes: a first substrate 10 and a first insulating package body 20, a conductive structure 30 arranged above the first substrate 10; and an electronic device 40.

The first substrate 10 may be a circuit board, may be a lead frame (LF), and also may be a chip or an electronic device etc., stacked below. In some embodiments, the first substrate 10 has on it a plurality of solder pads 11, the solder pads 11 herein refer to the solder pads required in order to connect the electronic devices 40 outside the first insulating package body 20. The conductive structure 30 is located on the first substrate 10 and is electrically connected with the solder pads 11 on the first substrate 10. In some embodiments, the conductive structure 30 includes a second substrate 31 and conductive pillars 32 located above it. The second substrate 31 can be electrically connected with the solder pads 11 on the first substrate through solder balls 33 at the bottom of the second substrate 31 or other means. The conductive pillars 32 may be solid conductive pillars, and also may be hollow conductive pillars, and their cross-section may be of various shapes, the specific structure is described in the aforementioned manufacturing method of the conductive structure 30. In some embodiments, the number of conductive pillars 32 is equal to or greater than the number of solder pads 11. In some embodiments, the area of the top end of the conductive pillars 32 is greater than the area of the solder pads 11.

The first insulating package body 20 is formed on the upper surface of the first substrate 10, and the material of the first insulating package body 20 is resin, which can be manufactured using methods such as mold injection molding, etc. The first insulating package body 20 covers at least a part of the side walls of the conductive structure 30, and electronic components, leads, solder pads, etc. that do not need to be exposed can be packaged in the first insulation package body 20.

In some embodiments, the top of the conductive structure 30 is flush with or higher than the upper surface of the first insulating package body 20. When the top of the conductive structure 30 is flush with the first insulating package body 20, the tops of the two are located in the same plane, which facilitates the formation of the first insulating package body 20.

In some embodiments, the conductive structure 30 further includes a second insulating package body 34, and the second insulating package body 34 is arranged above the second substrate 31, packages at least a part of the conductive pillars 32 and exposes the top end of the conductive pillars 32. The second insulating package body 34 may be an independent package body, and also may be formed in one-piece with the first insulating package body 20. When the second insulating package body 34 is an independent package body, the conductive structure 30 can serve as a modular structural component, and may be pre-designed according to the shape, size of the first substrate 10, and the shape, size and position of the solder pads 11 to simplify the process and shorten the manufacturing, and it can even be applicable to various different package structures. When the second insulating package body 34 is formed in one-piece with the first insulating package body 20, one molding process can be saved, which reduces manufacturing time and costs, and the conductive structure 30 is merged with the first insulating package body 20 in to a whole, which improves structural strength.

Electronic device 40 can be fixed above the first insulating package body 20 through methods such as silver paste or chip bonding film, etc., and electrically connected with solder pads 11 on the first substrate 10 through conductive structure 30. In some embodiments, adjustments to the solder pads 11 can be achieved by configuration in aspects such as number, shape, area of top end, and layout, etc., of conductive pillars 32, to reduce the difficulty of connection with the electronic device 40 and improve the yield. The electronic device 40 may also be fixed above the first insulating package body 20 through other methods, for example, electronic device 40 is mounted in a flip-chip manner above the conductive structure 30 and the first insulating package body 20, so that the top end of the conductive pillars 32 can be connected more tightly.

In some embodiments, the package structure for an electronic device provided by the present disclosure further includes an outer cover 50, which is arranged on the first substrate 10 or the first insulating package body 20 and is used to enclose the electronic device 40 and the conductive structure 30. The outer cover 50 may be of metal material, resin material, etc., and its material and design are selected according to actual needs. For example, when the electronic device 40 is an optical device that requires light sensing, at least a part of the outer cover 50 should be able to transmit light; when the electronic device 40 needs to come into contact with the outside air, then the outer cover 50 may be arranged as a non-sealed structure, for example, at least one channel communicating with the outside is arranged.

It should be noted that although the present disclosure is explained by taking MEMS package as an example, the present disclosure is not limited to MEMS package and may be applicable to any similar package situation.

Those skilled in the art may understand the disclosed embodiments and make other modifications thereto by reading the description, the disclosed contents, the accompanying drawings, and the appended claims. In the claims, the wording “comprising” does not exclude other elements or steps, and the wordings “a” or “one” do not exclude plurality. In practical implementation of the present disclosure, a component may perform the functions of a plurality of technical features referenced in the claims. Any reference numerals in the claims should not be construed as limiting the scope.

What is claimed is:

1. A package structure, comprising:
a first substrate;
a plurality of solder pads on the first substrate;
a conductive structure on the first substrate and electrically connected to the solder pads;
a first insulating package body on an upper surface of the first substrate and covering at least a portion of sidewalls of the conductive structure; and
a first electronic device fixed on the first insulating package body and electrically connected to the solder pads via the conductive structure.

2. The package structure according to claim 1, wherein the conductive structure comprises:
a second substrate; and
conductive pillars on the second substrate, wherein the second substrate is electrically connected to the solder pads via solder balls.

3. The package structure according to claim 2, wherein the conductive structure further comprises:
a second insulating package body on the second substrate, encapsulating at least a portion of the conductive pillars and exposing top ends of the conductive pillars.

4. The package structure according to claim 3, wherein the second insulating package body and the first insulating package body are formed in one piece.

5. The package structure according to claim 1, wherein a top of the conductive structure is flush with or higher than an upper surface of the first insulating package body.

6. The package structure according to claim 1, further comprising:
a cover on the first substrate or the first insulating package body, and configured to enclose the first electronic device and the conductive structure.

7. The package structure according to claim 6, wherein the cover is at least partially light-transmissive or a non-sealed structure.

8. The package structure according to claim 7, wherein the cover is partially light-transmissive when the first electronic device is an optical device, or the cover is the non-sealed structure when the first electronic device is an electronic device configured to be in contact with air.

9. The package structure according to claim 6, wherein a material of the cover comprises at least one of metal or resin.

10. The package structure according to claim 1, further comprising:
a second electronic device arranged on the first substrate and encapsulated within the first insulating package body.

11. A package method, comprising:
fixing a conductive structure on a first substrate and electrically connecting to a plurality of solder pads on the first substrate;
forming a first insulating package body on the first substrate via a molding process, and exposing a top of the conductive structure; and
fixing a first electronic device on the first insulating package body and electrically connecting the first electronic device to the plurality of solder pads via the conductive structure.

12. The package method according to claim 11, wherein before fixing a conductive structure on a first substrate and electrically connecting to a plurality of solder pads on the first substrate, the method further comprises:
providing the conductive structure.

13. The package method according to claim 12, wherein the providing the conductive structure further comprises:
forming a second insulating package body on a second substrate via a molding process;
forming holes in the second insulating package body, wherein one end of each of the holes is connected to the second substrate, and another end of each of the holes extends through an upper surface of the second insulating package body; and
plating or filling conductive material within the holes to form conductive pillars on the second substrate.

14. The package method according to claim 12, wherein the providing the conductive structure further comprises:
arranging conductive pillars on a second substrate.

15. The package method according to claim 14, wherein the providing the conductive structure further comprises:
forming a second insulating package body on the second substrate via a molding process; and
encapsulating at least a portion of the conductive pillars and exposing top ends of the conductive pillars.

16. The package method according to claim 15, wherein the first insulating package body is formed on the first substrate and the second insulating package body is formed on the second substrate simultaneously via the molding process, and at least the portion of the conductive pillars is encapsulated, and the top ends of the conductive pillars are exposed.

17. The package method according to claim 11, wherein after fixing a first electronic device on the first insulating package body and electrically connecting to the plurality of solder pads via the conductive structure, the method further comprises:
arranging a cover on the first substrate or the first insulating package body, and the cover is configured to enclose the first electronic device and the conductive structure.

18. The package method according to claim 17, wherein the cover is at least partially light-transmissive or a non-sealed structure.

19. The package method according to claim 18, wherein the cover is partially light-transmissive when the first electronic device is an optical device, or the cover is the non-sealed structure when the first electronic device is an electronic device configured to be in contact with air.

20. The package method according to claim 11, wherein before forming a first insulating package body on the first substrate via a molding process, the method further comprises:
arranging a second electronic device on the first substrate, wherein the second electronic device is subsequently encapsulated within the first insulating package body.
